(19) United States
(12) Patent Application Publication
(10) Pub. No.: US 2023/0178701 A1
(43) Pub. Date: Jun. 8, 2023

(54) ELECTRONIC DEVICE

(71) Applicant: InnoLux Corporation, Miao-Li County (TW)

(72) Inventors: Chao-Sen YANG, Miao-Li County (TW); Chueh-Yuan NIEN, Miao-Li County (TW); Chao-Chin SUNG, Miao-Li County (TW); Chien-Tzu CHU, Miao-Li County (TW)

(21) Appl. No.: 18/051,543

(22) Filed: Nov. 1, 2022

(30) Foreign Application Priority Data
Dec. 7, 2021 (CN) 202111483418.9

(51) Int. Cl. H01L 33/62

(52) U.S. Cl. CPC H01L 33/62; H01L 2224/16227; H01L 24/16

(57) ABSTRACT

An electronic device includes a substrate; a first bonding pad and a second bonding pad disposed on the substrate; an electronic assembly on the substrate; a first conductive structure; and a second conductive structure. The electronic assembly includes a third bonding pad and a fourth bonding pad. The third bonding pad is electrically connected to the first bonding pad by the first conductive structure and the fourth bonding pad is electrically connected to the second bonding pad by the second conductive structure. The thickness of the first conductive structure and the thickness of the second conductive structure are greater than or equal to 10 μm and less than or equal to 30 μm.

### CROSS REFERENCE TO RELATED APPLICATIONS

This application claims priority of China Patent Application No. 202111483418.9, filed on Dec. 7, 2021, the entirety of which is incorporated by reference herein.

### BACKGROUND OF THE INVENTION

### Field of the Invention

The present invention relates to a device, and, in particular, to an electronic device.

### Description of the Related Art

With the development of digital technology, electronic devices are widely used in all aspects of daily life. In the manufacturing industry of electronic devices, the goal is to improve the reliability of the electronic devices and reduce their manufacturing cost.

### BRIEF SUMMARY OF THE INVENTION

An embodiment of the present invention provides an electronic device comprising: a substrate; a first bonding pad and a second bonding pad disposed on the substrate; an electronic assembly on the substrate and having a third bonding pad and a fourth bonding pad; a first conductive structure electrically connecting the first bonding pad to the third bonding pad; a second conductive structure electrically connecting the second bonding pad to the fourth bonding pad, wherein the thickness of the first conductive structure and the thickness of the second conductive structure are greater than or equal to 10 μm and less than or equal to 30 μm.

### BRIEF DESCRIPTION OF THE DRAWINGS

The present invention can be more fully understood by reading the subsequent detailed description and examples with references made to the accompanying drawings, wherein:

FIG. 1 illustrates a cross-sectional schematic view of an electronic device according to some embodiments of the present disclosure.

FIG. 2 shows a bottom view of an electronic assembly in the electronic device shown in FIG. 1 according to some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The following description is a detailed description of components of some embodiments of the present disclosure. It should be understood that the following description provides many different embodiments or examples for implementing different aspects of some embodiments of the present disclosure. The particular components and arrangements described below are intended only to briefly and clearly describe some embodiments of the present disclosure. The particular components and arrangements described below are, of course, intended to be examples only and not limitations of the present disclosure. In addition, symbols or labels may be repeated in different embodiments. These repetitions are for the purpose of simply and clearly describing some embodiments of the present disclosure and do not imply any correlation between the different embodiments and/or structures discussed. Further, a first material layer on or above a second material layer comprises cases in which the first material layer is in direct contact with the second material layer. Alternatively, a first material layer on or above a second material layer comprises cases in which there may be one or more other material layers spaced apart the first material layer and the second material layer, such that the first material layer and the second material layer may not be in direct contact with each other.

In the present disclosure, the length, width, thickness, height, or area of the components or the distance or spacing between the components may be measured using an optical microscope (OM), a scanning electron microscope (SEM), an alpha-step (α-step), an ellipsometer, or other suitable means. In detail, according to some embodiments, a scanning electron microscope may be used to obtain a cross-sectional image of the structure of the components to be measured and to measure the width, thickness, height or area of each component, or the distance or spacing between the components, but the disclosure is not limited thereto. In addition, there may be a certain amount of error between the values or directions of any two comparisons.

Here, the term “about”, “approximately”, “substantially”, as used herein usually indicates a value of a given value or range that varies within 20%, preferably within 10%, and more preferably within 5%, or within 3%, or within 2%, or within 1%, or within 0.5%. Here, the given value are approximate value, i.e., “about”, “approximately”, or “substantially”, may be implied without specifying “about”, “approximately”, or “substantially”. Here, the term “less than or equal to” means including a given value and a value below that given value, and the term “greater than or equal to” means including a given value and a value above that given value. Conversely, the term “less than” indicates a value that is less than a given value and does not comprise that given value, and the term “greater than” indicates a value that is more than a given value and does not comprise that given value. For example, “greater than or equal to a” means including values of a and above, and “greater than a” means including values that exceed a but not including a.

It should be understood that, although the terms “first”, “second”, “third”, etc., may be used herein to describe various components, constituents, regions, layers, and/or portions, such components, constituents, regions, layers, and/or portions do not be limited by the terms. These terms are used only to distinguish one component, constituent, region, layer, and/or portion from another component, constituent, region, layer, and/or portion. Accordingly, a first component, constituent, region, layer, and/or portion discussed below may be referred to as a second component, constituent, region, layer, and/or portion without departing from teachings of some embodiments of the present disclosure.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

Some embodiments of the present disclosure are understood from the following detailed description when read with the accompanying figures. The accompanying figures of the embodiments of the present disclosure are also considered to be a part of the present disclosure. It should be understood that, the actual scale of the devices and components is not shown in the accompanying figures of the embodiments of the present disclosure. The shape and thickness of the embodiments may be exaggerated in the accompanying figures to clearly show the features of the embodiments of the present disclosure. In addition, the structure and devices in the accompanying figures are shown schematically in order to clearly show the features of the embodiments of the present disclosure.

In some embodiments of the present disclosure, relative terms such as “down”, “up”, “horizontal”, “vertical”, “below”, “above”, “top”, “bottom”, etc. should be understood to refer to the orientation shown in the paragraph and related figures. The relative terms are used for illustrative purposes and does not imply that the devices described need to be manufactured or operated in a particular orientation. Unless otherwise defined, the terms “joint” and “connect” can mean that the two structures are in direct contact, or that the two structures are not in direct contact and other structures are located between the two structures. The terms “joint” and “connect” may also comprise cases in which both structures are movable, or where both structures are fixed.

The electronic device of the present disclosure may comprise a display device, a backlight device, an antenna device, a sensing device, or a splicing device, but not limited thereto. The electronic device may be a bendable or flexible electronic device. The display device may be a non-self-emitting display device or self-emitting display device. The antenna device may be a liquid crystal antenna device or non-liquid crystal antenna device. The sensing device may be a sensing device that senses capacitance, light, heat, or ultrasound, but the disclosure is not limited thereto. Electronic components may comprise passive components and active components, such as capacitors, resistors, inductors, diodes, transistors, etc. The diodes may comprise light-emitting diodes or photoelectric diodes. The diodes may comprise organic light-emitting diodes or inorganic light-emitting diodes. The light-emitting diodes may comprise, for example, organic light-emitting diodes (OLED), mini light-emitting diodes (mini LED), micro light-emitting diodes (micro LED), or quantum dot light-emitting diodes (quantum dot LED), but the disclosure is not limited thereto. The splicing device may be, for example, display splicing devices or antenna splicing devices, but the disclosure is not limited thereto. It should be noted that the electronic device can be any combination of the aforementioned, but the disclosure is not limited thereto.

Notably, the term “substrate” in the following may comprise components already formed on a transparent substrate and various films covering a base substrate. A plurality of desired active components (transistor assemblies) may have been formed above the substrate. In order to simplify the accompanying figures, the substrate is shown as a flat substrate.

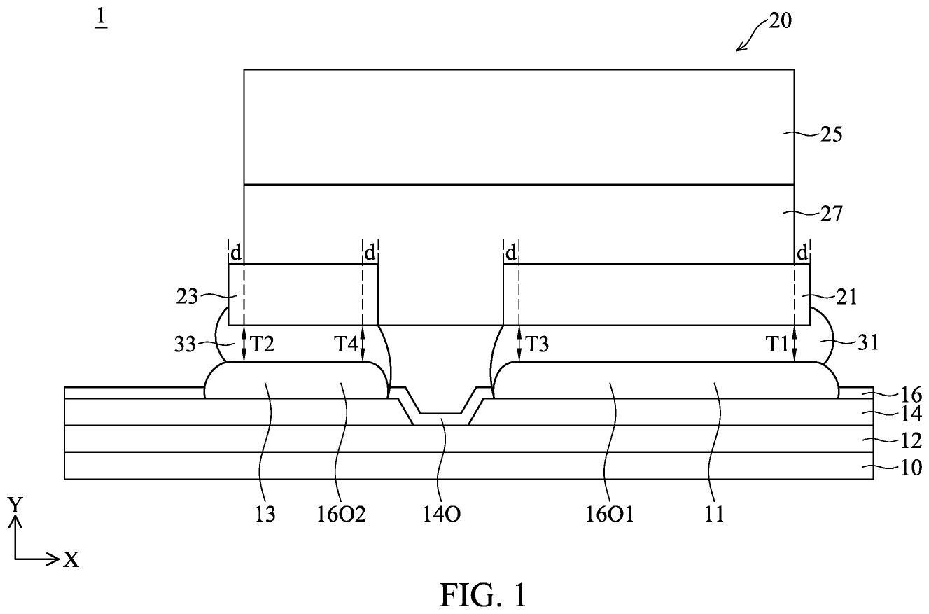

FIG. 1 illustrates a cross-sectional schematic view of an electronic device 1 according to some embodiments of the present disclosure. As shown in FIG. 1, the electronic device 1 may comprise a substrate 10, a first bonding pad 11 and a second bonding pad 13 disposed on the substrate, an electronic assembly 20, a first conductive structure 31, and a second conductive structure 33. The electronic assembly 20 is over the substrate 10 and electrically connected to the first bonding pad 11 and the second bonding pad 13 disposed on the substrate 10 through the first conductive structure 31 and the second conductive structure 33. In the following, the electronic device 1 shown in FIG. 1 is used as an example to explain in detail the electronic device of the present disclosure.

The substrate 10 in the electronic device 1 may comprises a substrate of an integrated circuit (not shown) electrically connected to the electronic assembly 20. The integrated circuit may comprise, for example, a microprocessor, a memory element, and/or other components. The integrated circuit may also comprise various passive components and/or active components, such as thin-film resistors, other types of capacitors, such as metal-insulator-metal capacitors (MIMCAP), inductors, diodes, metal-oxide-semiconductor field-effect transistors (MOSFETs), complementary MOS transistors, bipolar junction transistors (BJTs), laterally diffused MOS transistors, high-power MOS transistors, thin film transistors, or other types of transistors.

An first insulating layer 12 may be formed on the substrate 10. In some embodiments, the first insulating layer 12 may cover the entire surface of the substrate 10. The first insulating layer 12 may comprise an insulating layer formed of inorganic insulating materials, organic insulating materials, other suitable materials, or combinations thereof. The organic insulating materials may comprise polymers, such as polyethylene terephthalates (PET), polyimide, polycarbonates, epoxy resins, polyethylenes, benzocyclobutene (BCB) polymers, polyacrylates, or any combinations thereof, but the present disclosure is not limited thereto. The inorganic insulating materials may comprise metal oxides, such as aluminum oxides, strontium oxides, aluminum trioxides, titanium oxides; silicon-containing compounds, such as silicon oxides, silicon nitrides, hydrogen silicates (HSQ), poly-siloxanes, or any combinations thereof, but the present disclosure is not limited thereto. The above layer may comprise a single layer or multiple layers, depending on the needs of different embodiments of the present disclosure.

A metal layer 14 may be formed on the first insulating layer 12, as shown in FIG. 1. The metal layer 14 may comprise copper, aluminum, molybdenum, tungsten, gold, chromium, nickel, platinum, titanium, iridium, rhodium, alloys of the above, any combination of the above, or other metallic material with good electrical conductivity. In some embodiments, the metal layer 14 may comprise copper.

Processes for patterning the metal layer 14 may comprise a printing process, an ink jet process, an electroplating process, a chemical plating process, a deposition process, a photolithography process, an etching process, or other commonly used processes, but the present disclosure is not limited thereto. The deposition processes may comprise a chemical vapor deposition (CVD) processes, a sputtering processes, a resistive heating evaporation processes, an electron beam evaporation processes, or any other suitable deposition processes. In some embodiments of the present disclosure, the chemical vapor deposition processes may be a low pressure chemical vapor deposition (LPCVD) process, a low temperature chemical vapor deposition (LTCVD) process, a rapid thermal chemical vapor deposition (RTCVD) process, a plasma enhanced chemical vapor deposition (PECVD) process, an atomic layer deposition (ALD) process, or other commonly used processes, but the present disclosure is not limited thereto. The photolithography process comprises coating (e.g., rotational coating) photoresist, soft baking, photomask alignment, exposure, post-exposure baking, developing the photoresist, rinsing, drying (e.g., hard baking), other suitable processes, or any combinations thereof. Alternatively, the photolithography process may be performed by or replaced by other suitable processes, such as an unshielded lithography process, an electron-beam writing process, and an ion-beam writing process. The etching process may comprise a dry etching process, a wet etching process, or other etching processes, but the present disclosure is not limited thereto.

As shown in FIG. 1, the electronic device 1 may comprise a first opening 140, wherein the first opening 140 may be formed by patterning the metal layer 14. In some embodiments, the first opening 140 may expose a portion of the first insulating layer 12. As shown in FIG. 1, the second insulating layer 16 is formed on the metal layer 14. In some embodiments, the second insulating layer 16 is formed on the metal layer 14 and on sidewalls of the first opening 140 in the metal layer 14. The second insulating layer 16 may be formed of inorganic insulating materials, organic insulating materials, other suitable materials, of any combinations thereof. The materials for forming the second insulating layer 16 may be the same as or different from the materials for forming the first insulating layer 12. The electronic device 1 may comprise a second opening 1601 and a third opening 1602, wherein the second opening 1601 and the third opening 1602 may be formed by patterning the second insulating layer 16. In some embodiments, the second opening 1601 and the third opening 1602 may expose a portion of the metal layer 14.

The first bonding pad 11 is formed in the second opening 1601 and is formed on the metal layer 14 exposed by the second opening 1601. The second bonding pad 13 is formed in the third opening 1602 and is formed on the metal layer 14 exposed by the third opening 1602. In some embodiments, the size of the first bonding pad 11 and the second bonding pad 13 may be determined by the size of the second opening 1601 and the third opening 1602 respectively. The materials of the first bonding pad 11 and the second bonding pad 13 may comprise copper, aluminum, molybdenum, tungsten, gold, chromium, nickel, platinum, titanium, iridium, rhodium, alloys of the above, or other metallic materials with good electrical conductivity, or any combination thereof. The materials used to form the first bonding pad 11 and the second bonding pad 13 may be the same as or different from the materials used to form the metal layer 14. In some embodiments, the first bonding pad 11 and the second bonding pad 13 may comprise a single layer structure (e.g., a metallic material such as nickel) or a double layer structure (e.g., a metallic material such as nickel and gold).

Processes for patterning the first bonding pad 11 and the second bonding pad 13 may comprise a printing process, an ink jet process, an electroplating process, a chemical plating process, a deposition process, a photolithography process, an etching process, or other commonly used processes, but the present disclosure is not limited thereto. The deposition processes may comprise a chemical vapor deposition (CVD) processes, a sputtering processes, a resistive heating evaporation processes, an electron beam evaporation processes, or any other suitable deposition processes. In some embodiments of the present disclosure, the chemical vapor deposition processes may be a low pressure chemical vapor deposition (LPCVD) process, a low temperature chemical vapor deposition (LTCVD) process, a rapid thermal chemical vapor deposition (RTCVD) process, a plasma enhanced chemical vapor deposition (PECVD) process, an atomic layer deposition (ALD) process, or other commonly used processes, but the present disclosure is not limited thereto. The photolithography process comprises coating (e.g., rotational coating) photoresist, soft baking, photomask alignment, exposure, post-exposure baking, developing the photoresist, rinsing, drying (e.g., hard baking), other suitable processes, or any combination thereof. Alternatively, the photolithography process may be performed by or replaced by other suitable processes, such as an unshielded lithography process, an electron-beam writing process, and an ion-beam writing process. The etching process may comprise a dry etching process, a wet etching process, or other etching processes, but the present disclosure is not limited thereto.

The embodiment shown in FIG. 1 is illustrated with an example in which the electronic assembly 20 is a light-emitting unit, but the present disclosure is not limited thereto. The electronic assembly in this disclosure may be any suitable assemblies. The electronic assembly 20 shown in FIG. 1 may comprise a light-emitting portion 25, a wire frame 27, a third bonding pad 21, and a fourth bonding pad 23. As shown in FIG. 1, the light-emitting portion 25 may be disposed on the third bonding pad 21 and the fourth bonding pad 23. The wire frame 27 may be disposed between the light-emitting portion 25 and the third bonding pad 21 and between the light-emitting portion 25 and the fourth bonding pad 23.

The material of the third bonding pad 21 and the fourth bonding pad 23 may comprise copper, aluminum, molybdenum, tungsten, gold, chromium, nickel, platinum, titanium, iridium, rhodium, alloys of the above, or other metallic materials with good electrical conductivity, or any combination thereof. The materials for forming the third bonding pad 21 and the fourth bonding pad 23 may be the same as or different from the materials for forming the metal layer 14. The materials for forming the third bonding pad 21 and the fourth bonding pad 23 may be the same as or different from the materials for forming the first bonding pad 11 and the second bonding pad 13. In some embodiments, the third bonding pad 21 and the fourth bonding pad 23 may comprise copper.

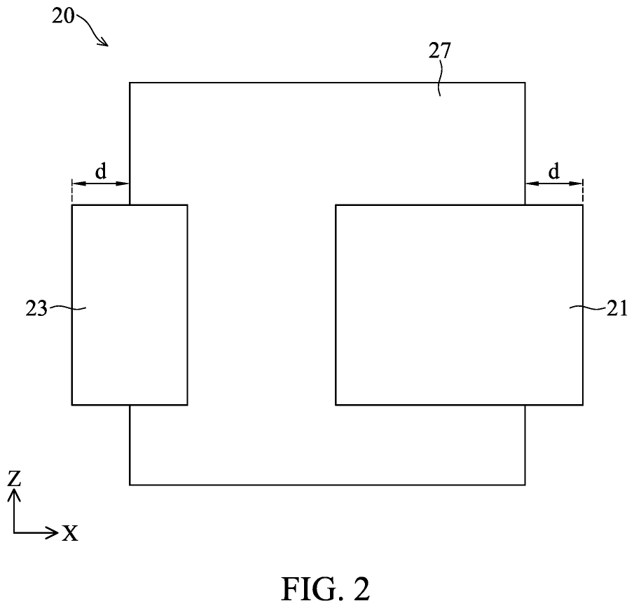

FIG. 2 shows a bottom view of the electronic assembly 20 in the electronic device 1 shown in FIG. 1 according to some embodiments of the present disclosure. As shown in FIG. 2 and FIG. 1, the third bonding pad 21 protrudes beyond the wire frame 27 by a distance d in a +X direction, and the fourth bonding pad 23 protrudes beyond the wire frame 27 by the distance d in a −X direction. Hereinafter, the side of the third bonding pad 21 which protrudes beyond the wire frame 27 is referred to as an outer side of the third bonding pad 21 and the side opposite the outer side is referred to as an inner side of the third bonding pad 21. Similarly, the side of the fourth bonding pad 23 which protrudes beyond the wire frame 27 is referred to as an outer side of the fourth bonding pad 23, and the side opposite the outer side is referred to as an inner side of the fourth bonding pad 23. In some embodiments, as shown in FIG. 1, a length of the third bonding pad 21 in the X direction may be shorter than or equal to a length of the first bonding pad 11 in the X direction. A length of the fourth bonding pad 23 in the X direction may be shorter than or equal to a length of the second bonding pad 13 in the X direction. In some embodiments, the area of the third bonding pad 21 may be greater than the area of the fourth bonding pad 23, as shown in FIG. 2.

The first conductive structure 31 is disposed between the third bonding pad 21 and the first bonding pad 11 to electrically connect the first bonding pad 11 and the third bonding pad 21. The second conductive structure 33 is disposed between the fourth bonding pad 23 and the second bonding pad 13 to electrically connect the second bonding pad 13 and the fourth bonding pad 23. The materials of the first conductive structure 31 and the second conductive structure 33 may comprise copper, aluminum, molybdenum, tungsten, gold, chromium, nickel, platinum, titanium, iridium, rhodium, tin, alloys of the above, or other metallic materials with good electrical conductivity, or any combination thereof. The materials for forming the first conductive structure 31 and the second conductive structure 33 may be the same as or different from the materials for forming the third bonding pad 21 and the fourth bonding pad 23. The materials for forming the first conductive structure 31 and the second conductive structure 33 may be the same as or different from the materials for forming the first bonding pad 11 and the second bonding pad 13. The materials for forming the first conductive structure 31 and the second conductive structure 33 may be the same as or different from the materials for forming the metal layer 14. In some embodiments, the first conductive structure 31 and the second conductive structure 33 may comprise tin.

Processes for patterning the first conductive structure 31 and the second conductive structure 33 may comprise a printing process, an ink jet process, an electroplating process, a chemical plating process, a deposition process, a photolithography process, an etching process, or other commonly used processes, but the present disclosure is not limited thereto. The deposition processes may comprise a chemical vapor deposition (CVD) processes, a sputtering processes, a resistive heating evaporation processes, an electron beam evaporation processes, or any other suitable deposition processes. In some embodiments of the present disclosure, the chemical vapor deposition processes may be a low pressure chemical vapor deposition (LPCVD) process, a low temperature chemical vapor deposition (LTCVD) process, a rapid thermal chemical vapor deposition (RTCVD) process, a plasma enhanced chemical vapor deposition (PECVD) process, an atomic layer deposition (ALD) process, or other commonly used processes, but the present disclosure is not limited thereto. The photolithography process comprises coating (e.g., rotational coating) photoresist, soft baking, photomask alignment, exposure, post-exposure baking, developing the photoresist, rinsing, drying (e.g., hard baking), other suitable processes, or any combination thereof. Alternatively, the photolithography process may be performed by or replaced by other suitable processes, such as an unshielded lithography process, an electron-beam writing process, and an ion-beam writing process. The etching process may comprise a dry etching process, a wet etching process, or other etching processes, but the present disclosure is not limited thereto.

In some embodiments, as shown in FIG. 1, a length of the first conductive structure 31 in the X direction may be longer than or equal to a length of the third bonding pad 21 in the X direction. A length of the second conductive structure 33 in the X direction may be longer than or equal to a length of the fourth bonding pad 23 in the X direction.

The first conductive structure 31 has a first external thickness T1 and a first internal thickness T3. The second conductive structure 33 has a second external thickness T2 and a second internal thickness T4. In this disclosure, the term “the thickness of the first conductive structure” refers to the first external thickness T1 or the first internal thickness T3. The term “thickness of the second conductive structure” refers to the second external thickness T2 or the second internal thickness T4. The term “first external thickness T1” refers to a height of the first conductive structure 31 in the Y direction. The height is measured at a position of the first conductive structure 31 which is corresponding to the edge of the wire frame 27. That is, the height of the first conductive structure 31 is measured at a position of the first conductive structure 31 which is corresponding to a position of the third bonding pad 21 which is spaced from the outer side of the third bonding pad 21 by a distance d. The term “second external thickness T2” refers to a height of the second conductive structure 33 in the Y direction. The height is measured at the position of the second conductive structure 33 which is corresponding to the edge of the wire frame 27. That is, the height of the second conductive structure 33 is measured at a position which is corresponding to a position of the fourth bonding pad 23 which is spaced from the outer side of the fourth bonding pad 23 by a distance d. The term “first internal thickness T3” refers to a height of the first conductive structure 31 in the Y direction. The height is measured a position of the first conductive structure 31 which is corresponding to a position of the third bonding pad 21 which is spaced from the inner side of the third bonding pad 21 by a distance d. The term “second internal thickness T4” refers to a height of the second conductive structure 33 in the Y direction. The height is measured a position of the second conductive structure 33 which is corresponding to a position of the fourth bonding pad 23 which is spaced from the inner side of the fourth bonding pad 23 by a distance d, as shown in FIG. 1. In some embodiments, the distance d may be about 10 to 300 μm. In some embodiments, the Y direction may be a normal direction the substrate 10 and the X direction may be a direction perpendicular to the Y direction.

In some embodiments, all of the first external thickness T1, the second external thickness T2, the first internal thickness T3, and the second internal thickness T4 are greater than or equal to about 10 μm and less than or equal to about 30 μm. In some embodiments, all of the first external thickness T1, the second external thickness T2, the first internal thickness T3, and the second internal thickness T4 are greater than or equal to about 15 μm and less than or equal to about 30 μm. In some embodiments, all of the first external thickness T1, the second external thickness T2, the first internal thickness T3, and the second internal thickness T4 are greater than or equal to about 20 μm and less than or equal to about 30 μm. That is, in some embodiments, the thickness of the first conductive structure is greater than or equal to about 10 μm and less than or equal to about 30 μm and the thickness of the second conductive structure is greater than or equal to about 10 μm and less than or equal to about 30 μm. In some embodiments, the thickness of the first conductive structure is greater than or equal to about 15 μm and less than or equal to about 30 μm. In some embodiments, the thickness of the second conductive structure is greater than or equal to about 15 μm and less than or equal to about 30 μm. In some embodiments, the thickness of the first conductive structure is greater than or equal to about 20 μm and less than or equal to about 30 μm. In some embodiments, the second conductive structure has a thickness that is greater than or equal to about 20 μm and less than or equal to about 30 μm. When the thickness of the conductive structure is less than about 10 μm, the thickness of the conductive structure is too thin. A conductive structure that is too thin will result in poor ductility or insufficient strength, and therefore the conductive structure will be prone to cracking, reducing the reliability of the final product. When the thickness of the conductive structure is greater than about 30 μm, the material used to form the conductive structure may be overflow. Overflowing of the material used to form the conductive structure will be detrimental to the subsequent process of the electronic device.

In some embodiments, the thickness difference between the first conductive structure 31 and the second conductive structure 33 is less than and/or equal to about 20 μm. In other embodiments, the thickness difference between the first conductive structure 31 and the second conductive structure 33 is less than and/or equal to about 15 μm. In other embodiments, the thickness difference between the first conductive structure 31 and the second conductive structure 33 is less than and/or equal to about 10 μm. In the disclosure, the thickness difference between the first conductive structure 31 and the second conductive structure 33 may be defined by the formula: [thickness difference=(T1 to T4)max−(T1 to T4)min]. That is, the thickness difference between the first conductive structure 31 and the second conductive structure 33 is obtained by minus the minimum value of the first external thickness T1 to the second internal thickness T4 from the maximum value of the first external thickness T1 to the second internal thickness T4. The smaller the thickness difference between the first conductive structure 31 and the second conductive structure 33 is better. When the thickness difference between the first conductive structure 31 and the second conductive structure 33 is too large (e.g., greater than about 20 μm), the stress will be excessively concentrated at a high point (i.e., where the thickness is thicker). Therefore, the conductive structures may be prone to local cracking and the reliability of a final product may be reduced.

Specific examples of the present disclosure are provided below to further illustrate the advantages of the present disclosure.

### Examples 1-4 and Comparative Examples 1-5

A light-emitting diode is used as the electronic assembly in each of Examples 1-4 and Comparative Examples 1-5. When viewed from a bottom view or a top view, the light-emitting diode has a cathode bonding pad with a greater area and an anode bonding pad with a smaller area. The above relationship between the areas can be observed by an optical microscope. In Examples 1-4 and Comparative Examples 1-5, the electronic device is prepared by electrically connecting the bonding pad on the glass substrate of the thin film transistor (TFT) to the cathode bonding pad using a large tin block having a thickness as shown in Table 1, and electrically connecting the bonding pad on the glass substrate of the thin film transistor (TFT) to the anode bonding pad using a small tin block having a thickness as shown in Table 1.

TABLE 1

| | Thickness of small | | Thickness of large | | | | |
|---|---|---|---|---|---|---|---|
| | tin block (μm) | | tin block (μm) | | thickness | | |
| | external | internal | external | internal | difference | | material |
| | thickness | thickness | thickness | thickness | (μm) | crack | overflow |
| Example 1 | 14 | 14 | 16 | 21 | 7 | X | X |
| Example 2 | 21 | 25 | 18 | 19 | 7 | X | Δ |
| Example 3 | 26 | 26 | 26 | 29 | 3 | X | Δ |
| Example 4 | 10 | 15 | 24 | 30 | 20 | X | Δ |
| Comparative | 5 | 7 | 15 | 25 | 20 | ◯ | X |
| Example 1 | | | | | | | |
| Comparative | 11 | 9 | 9 | 8 | 3 | ◯ | X |
| Example 2 | | | | | | | |
| Comparative | 28 | 33 | 19 | 29 | 14 | X | ◯ |
| Example 3 | | | | | | | |
| Comparative | 34 | 36 | 19 | 32 | 17 | X | ◯ |
| Example 4 | | | | | | | |
| Comparative | 29 | 30 | 23 | 30 | 7 | X | ◯ |
| Example 5 | | | | | | | |

The term “external thickness” in Table 1 refers to the thickness of the tin block measured from a position corresponding to the position of the cathode bonding pad or the anode bonding pad of the light-emitting diode at 100 μm inward from the outer side thereof. The term “internal thickness” in Table 1 refers to the thickness of the tin block measured from a position of the tin block corresponding to the position of the cathode bonding pad or the anode bonding pad of the light-emitting diode at 100 μm inward from the inner side thereof. The existence of cracks in the large tin blocks and the small tin blocks of Examples 1-4 and Comparative Examples 1-5 was observed by a scanning electron microscope (Scanning Electron Microscope, SEM). “Δ” indicates that cracks are observed in the large tin block and/or the small tin block, and “X” indicates that no cracks are observed in the large tin block and/or the small tin block. The material overflow from the large tin block and/or the small tin block in Examples 1-4 and Comparative Examples 1-5 are observed by an optical microscope. “X” indicates that no tin beads observed at edges of the large tin block and/or the small tin block (tin beads may be formed due to the material overflow). “Δ” indicates that a tin bead with a diameter in a range from about 0 to 300 μm is observed at the edges of the large tin block and/or the small tin block. “O” indicates that a tin bead with a diameter greater than 300 μm is observed at the edges of the large tin block and/or the small tin block (indicates material overflow). A tin bead with a diameter greater than about 300 μm indicates that the amount of the material overflowed is much enough to adversely affect the subsequent process.

From Table 1 above, it can be seen that when the internal and external thicknesses of the large and small tin blocks are greater than or equal to about 10 μm and the thickness difference between the large and small tin blocks is less than or equal to about 20 μm, the tin blocks are less prone to cracking. When the internal and external thicknesses of the large and small tin blocks are less than or equal to about 30 μm, there is no material overflow or little material overflow, which does not adversely affect the subsequent process. Therefore, when the internal and external thicknesses of the large and small tin blocks are greater than or equal to about 10 μm and less than or equal to about 30 μm, and the difference between the thickness of the large tin block and the thickness of the small tin block is less than or equal to about 20 μm, the tin blocks are less prone to cracking and do not adversely affect the subsequent process. As a result, the electronic device structure disclosed herein can prevent the electronic assembly from dislodging from the substrate, reduce the formation of dark spots, and/or increase the reliability of the electronic device.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a substrate;
a first bonding pad and a second bonding pad disposed on the substrate;
an electronic assembly on the substrate and having a third bonding pad and a fourth bonding pad;
a first conductive structure electrically connecting the first bonding pad to the third bonding pad; and
a second conductive structure electrically connecting the second bonding pad to the fourth bonding pad, wherein a thickness of the first conductive structure and a thickness of the second conductive structure are greater than or equal to 10 μm and less than or equal to 30 μm.

2. The electronic device as claimed in claim 1, wherein an area of the third bonding pad of the electronic assembly is greater than an area of the fourth bonding pad of the electronic assembly.

3. The electronic device as claimed in claim 1, wherein the thickness of the first conductive structure or the thickness of the second conductive structure is greater than or equal to 15 μm and less than or equal to 30 μm.

4. The electronic device as claimed in claim 1, wherein the thickness of the first conductive structure is greater than or equal to 20 μm and less than or equal to 30 μm.

5. The electronic device as claimed in claim 1, wherein a difference between the thickness of the first conductive structure and the thickness of the second conductive structure is less than or equal to 20 μm.

6. The electronic device as claimed in claim 1, wherein materials of the first conductive structure and the second conductive structure are different from materials of the first bonding pad and the second bonding pad.

7. The electronic device as claimed in claim 1, wherein materials of the first conductive structure and the second conductive structure are different from materials of the third bonding pad and the fourth bonding pad.

8. The electronic device as claimed in claim 1, wherein the first conductive structure and the second conductive structure comprise tin.

9. The electronic device as claimed in claim 1, wherein the first conductive structure has a first external thickness and a first internal thickness, wherein the first external thickness is different from the first internal thickness.

10. The electronic device as claimed in claim 9, wherein a difference between the first external thickness and the first internal thickness is less than or equal to 20 μm.

11. The electronic device as claimed in claim 1, wherein the second conductive structure has a second external thickness and a second internal thickness, wherein the second external thickness is different from the second internal thickness.

12. The electronic device as claimed in claim 11, wherein a difference between the second external thickness and the second internal thickness is less than or equal to 20 μm.

13. The electronic device as claimed in claim 1, wherein the electronic assembly is a light-emitting unit.

14. The electronic device as claimed in claim 13, wherein the light-emitting unit comprises:
a light-emitting portion disposed on the third bonding pad and the fourth bonding pad; and
a wire frame disposed between the light-emitting portion and the third bonding pad and between the light-emitting portion and the fourth bonding pad.

15. The electronic device as claimed in claim 14, wherein the third bonding pad protrudes beyond the wire frame by a first distance.

16. The electronic device as claimed in claim 15, wherein the first distance is in a range of 10 to 300 μm.

17. The electronic device as claimed in claim 14, wherein the fourth bonding pad protrudes beyond the wire frame by a second distance.

18. The electronic device as claimed in claim 17 wherein the second distance is in a range of 10 to 300 μm.

19. The electronic device as claimed in claim 14, wherein the third bonding pad and the fourth bonding pad comprise copper.

20. The electronic device as claimed in claim 1, further comprise a metal layer between the substrate and the first bonding pad and the substrate and the second bonding pad.
